(19) United States
(12) Patent Application Publication
(10) Pub. No.: US 2025/0189558 A1
(43) Pub. Date: Jun. 12, 2025

(54) ELECTRICAL SOCKET WITH AN IMPROVED ELEVATING MECHANISM FOR A HEATING-DISSIPATION ASSEMBLY

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventor: MING-YUE CHEN, New Taipei (TW)

(21) Appl. No.: 18/973,623

(22) Filed: Dec. 9, 2024

(30) Foreign Application Priority Data
Dec. 7, 2023 (TW) 112147585

(51) Int. Cl. G01R 1/04; G01R 1/44

(52) U.S. Cl. CPC G01R 1/0458; G01R 1/44

(57) ABSTRACT

An electrical socket includes: a socket base; a supporting frame being pivotably connected with the socket base by a first shaft and having a locking portion to latch with the socket base; a heat-dissipation assembly retained on the supporting frame and having springs; and an operating member retained with a pair of first cams, the first cams being pivotably connected with the supporting frame by a pair of second shafts, each of the first cams having a long axis and a short axis, wherein the operating member is rotatable to orient the long axes of the first cams in an upright direction to push the heat-dissipation assembly away from the supporting frame by a gap and to orient the short axes of the first cams in the upright direction to reset the heat-dissipation assembly to move downwards by the springs.

### BACKGROUND OF THE INVENTION

### Field of the Invention

The present invention relates to an electrical socket for test a chip module, which has a heat-dissipation assembly.

### Description of Related Arts

China Patent No. 213484050 discloses a heat-dissipation assembly combination which includes a chip connector, a rotating member, and a heat dissipation assembly. The rotating member is pivoted to the chip connector and the heat dissipation assembly is installed on the rotating member. The heat dissipation assembly comprises a heat dissipation module with a copper block for heat dissipation and an elastic-increasing member. The elastic-increasing member comprises a first frame, a second frame, and a plurality of springs between the first frame and the second frame to generate elastic force. The copper block passes through the first frame and the second frame to abut against the chip module for heat dissipation. The elastic-increasing member transmits a large force to the copper block so that the copper block presses downwards against the chip module. However, when the heat dissipation rotates towards the chip connector, especially proximate to the chip module, the copper block might scrape the top face of the chip module.

Therefore, it is necessary to provide an improved electrical socket with a heat-dissipation assembly.

### SUMMARY OF THE INVENTION

The object of the present invention is to provide an electrical socket having a heat-dissipation assembly with an improved elevating mechanism.

To achieve the above object, an electrical socket for testing a chip module includes: a socket base having a chip-receiving area; a supporting frame being pivotably connected with the socket base by a first shaft at one end thereof and having a locking portion at another end thereof to latch with the socket base after the supporting frame is rotated to seat on the socket base; a heat-dissipation assembly retained on the supporting frame and having springs; and an operating member retained with a pair of first cams, the first cams being pivotably connected with the supporting frame by a pair of second shafts, each of the first cams having a long axis and a short axis, wherein the operating member is rotatable to orient the long axes of the first cams in an upright direction to push the heat-dissipation assembly away from the supporting frame by a gap and to orient the short axes of the first cams in the upright direction to reset the heat-dissipation assembly to move downwards by the springs.

Other advantages and novel features of the invention will become more apparent from the following detailed description of the present embodiment when taken in conjunction with the accompanying drawings.

### BRIEF DESCRIPTION OF DRAWINGS

FIG. 1 is a perspective view of an electrical socket in accordance with the present invention, wherein a heat-dissipation is in an opening state;

FIG. 2 is another perspective view of the electrical socket of FIG. 1;

FIG. 3 is a cross-sectional view of the electrical socket taken alone line A-A in FIG. 2;

FIG. 4 is a perspective view of an elevating mechanism and a supporting frame in FIG. 2;

FIG. 5 is a perspective view of the supporting frame in FIG. 4;

FIG. 6 is a partly exploded perspective view of the elevating mechanism in FIG. 4;

FIG. 7 is a perspective view of the electrical socket in a final state;

FIG. 8 is a cross-sectional view of the electrical socket taken alone line B-B in FIG. 7;

FIG. 9 is a perspective view of the elevating mechanism in the final state in FIG. 7;

FIG. 10 is a cross-sectional view of the electrical socket taken alone line C-C in FIG. 2; and

FIG. 11 is a cross-sectional view of the electrical socket taken alone line D-D in FIG. 2.

### DETAILED DESCRIPTION OF THE DRAWINGS

Reference will now be made in detail to the preferred embodiments of the present invention.

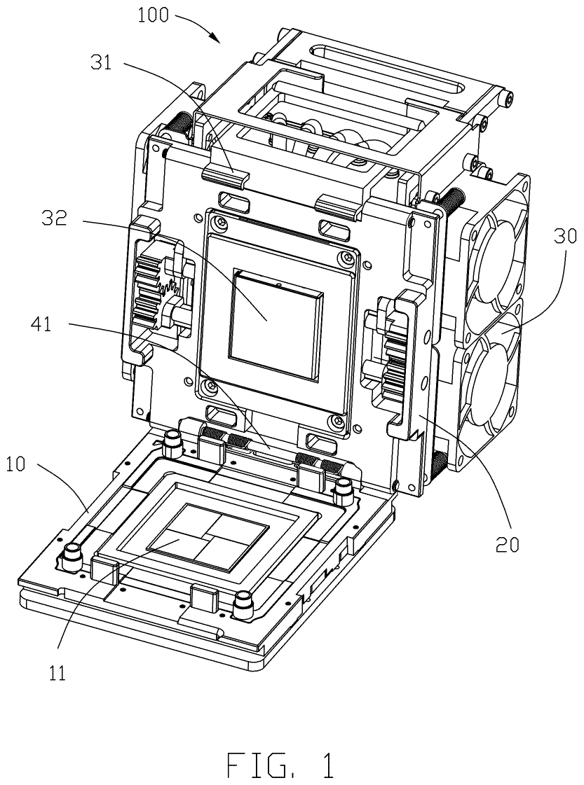

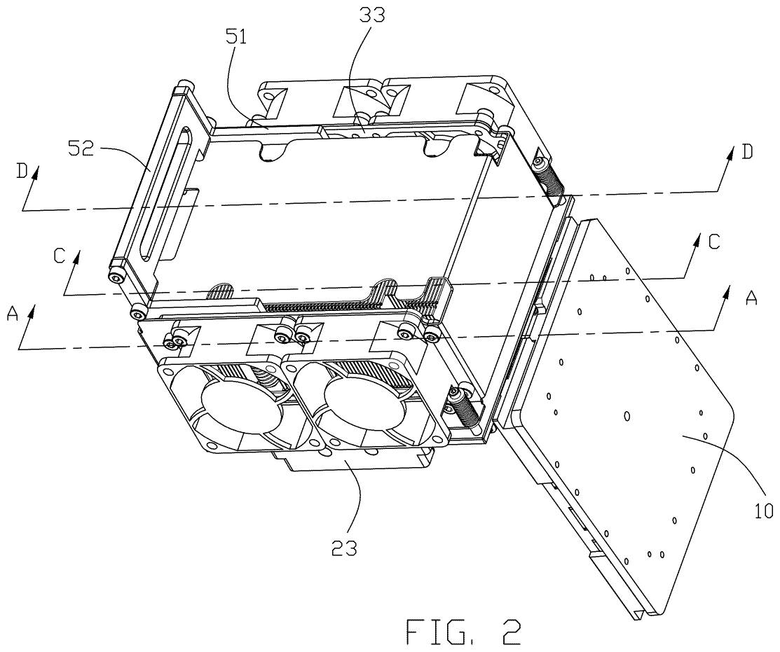

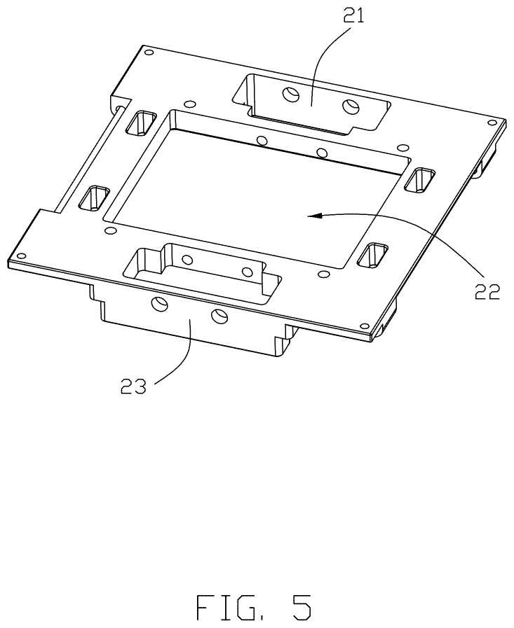

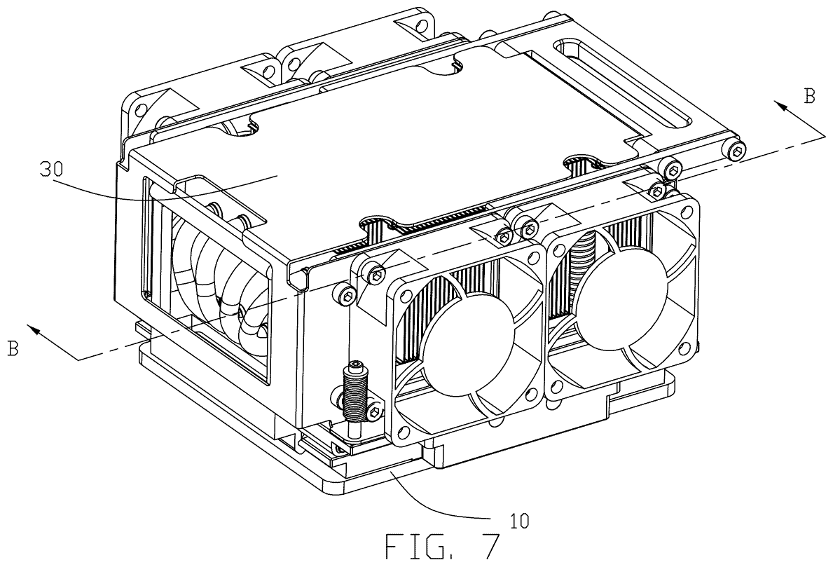

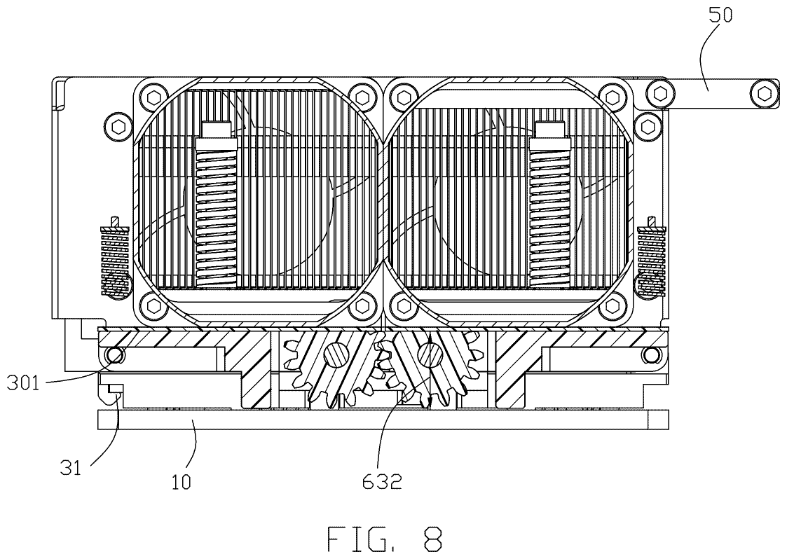

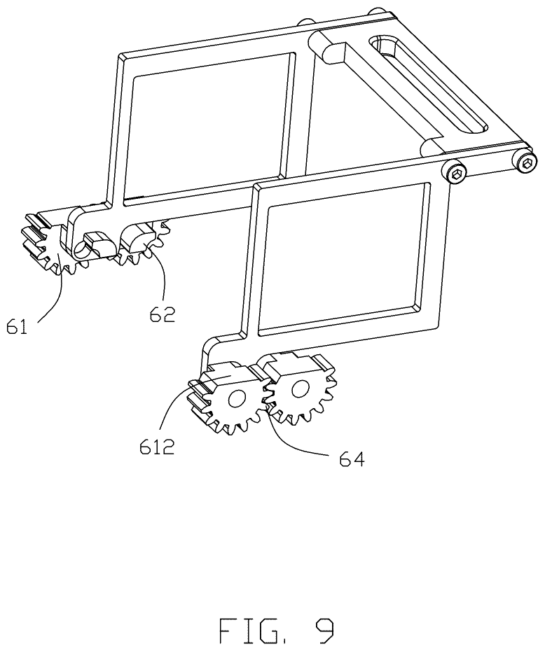

Referring to FIGS. 1-11, an electrical socket 100 of an embodiment of this present invention is a type of testing electrical socket which is adapted for testing a chip module such as CPU, DDR. As shown in FIGS. 1-2, the electrical socket 100 includes a socket base 10, a supporting frame 20 and a heat-dissipation assembly 30 with a dissipation head 32. The socket base 10 has a chip-receiving area 11 such as a cavity to receive the chip module, the chip-receiving area 11 is usually loaded with conductive terminals (not shown). The heat-dissipation assembly 30 is fitted on the supporting frame 20 and moves along the supporting frame 20, a first end of the supporting frames 20 and a first end of the socket base 10 are pivotably connected together by a first shaft 41, the heat-dissipation assembly 30 has a locking portion 31 at a second end thereof opposite to the first shaft 41. Combined with FIGS. 7-8, when the heat-dissipation assembly 30 rotates to the socket base 10, the locking portion 31 is latched to the socket base 10.

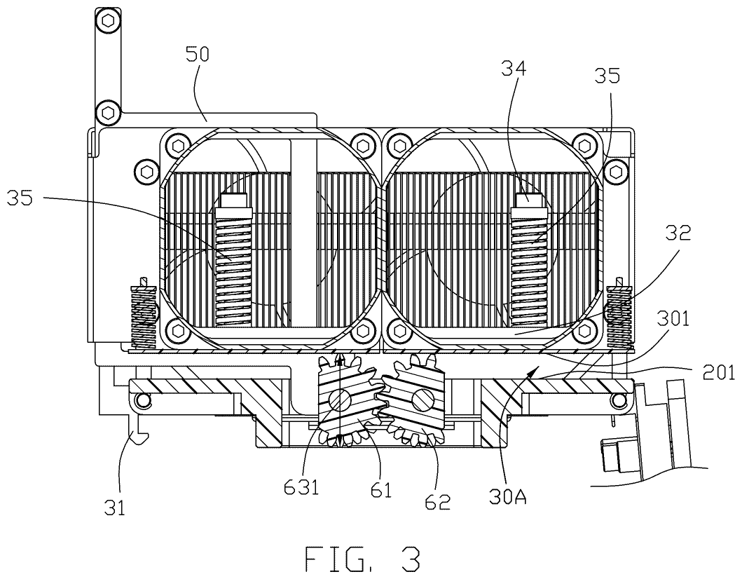

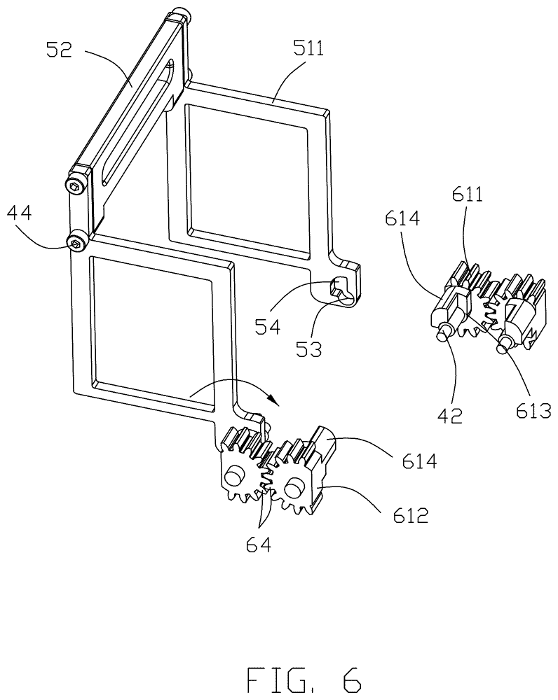

FIG. 3 shows a cross sectional view of the heat-dissipation assembly 30 in an opening state wherein the heating-dissipation assembly is separated from the supporting frame 20 with a gap 30A. When heat-dissipation assembly 30 and the supporting frame 20 rotate to seat on the socket base 10 before rotating the operating member 50, the heat-dissipation assembly 30 is not pressed, the heat-dissipation assembly 30 still separates from the supporting frame 20 with the gap 30A, which is defined as a seat state. FIG. 8 shows the heat-dissipation assembly is pressed downwards to arrive to a final state. In FIG. 3, a bottom face 301 is supported by long axis 631 of first cams 61 and the second cams 62, and separates from an upper face 201 of the supporting frame 20 with the gap 30A. At this moment, the dissipation head 32 separates from the chip module with the gap so as to avoid scraping the chip module. In FIG. 8, the bottom face 301 of the heat-dissipation assembly 30 is supported by short axis 632 of the first and second cams, the bottom face 301 moves downward and contact the upper face of the supporting frame 20. At this moment, the dissipation head 32 contacts the chip module to get a heat dissipation. In this embodiment, during the heat dissipation assembly 30 rotates from the opening state to the seat state wherein the heat-dissipation assembly 30 seat on the supporting frame 20 but is not pushed downwards, the dissipation head 32 separates from the chip module. Then, a user push or pull the operating member 50 as an arrow shown in FIG. 6, the heat-dissipation assembly 30 is pushed downwards in an upper and lower direction or an upright direction, without any slide movement of the dissipation head 32 on an upper face of the chip module to avoid scraping.

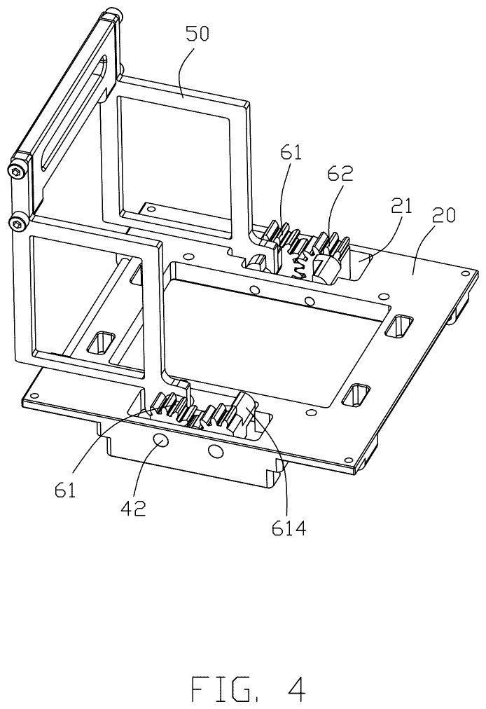

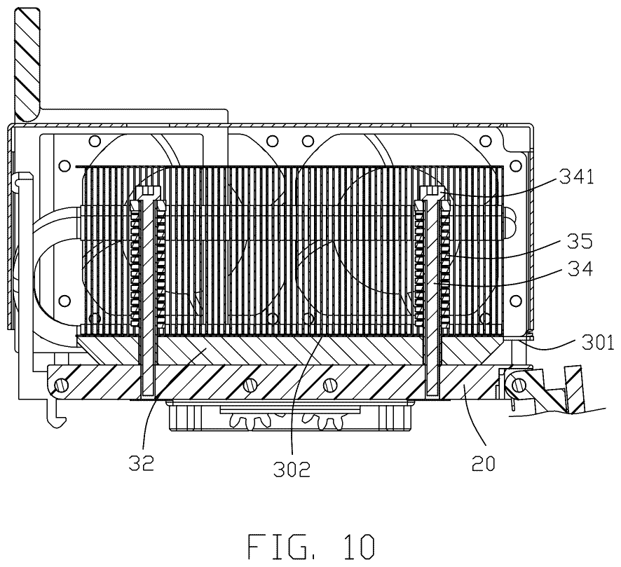

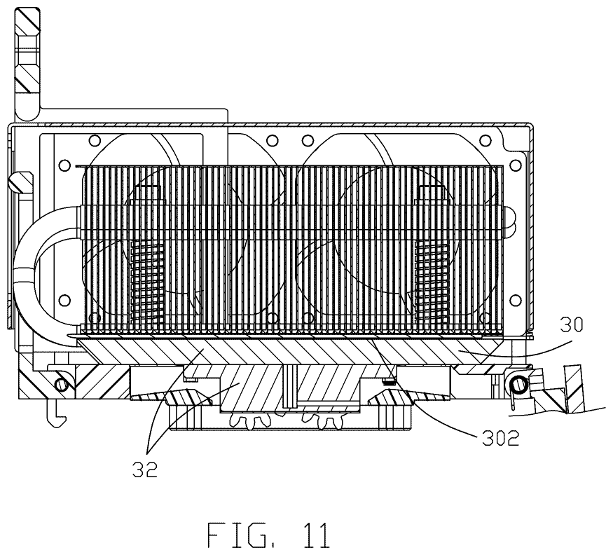

The downwards movement of the heat-dissipation assembly 30 will be described hereinafter. Referring to FIGS. 4-6, the electrical socket 10 further includes the operating member 50 and a pair of the first cams 61 located at two distal ends of the operating member 50. The supporting frame 20 has two receiving slots 21, a center opening 22 to allow the dissipation head 32 to go through, and two side receiving portions 23 extending downwards. The receiving slots 21 run through corresponding receiving portions 23. The two first cams 61 and corresponding ends of the operating member 50 are retained with a pair of second shafts 42 and are commonly received in corresponding receiving slots 21 by way of the second shafts 42 being pivoted to the supporting frame 20. Combined with FIG. 3, when the heat-dissipation assembly 30 rotates to seat on the socket base 10, the supporting frame 20 just seat on the socket base 10, lower ends of positioning posts 34 go across the dissipation head 32 and are retained with the supporting frame 20, and a spring 35 is set on each positioning post 34. The spring 35 is limited between an upper end 341 of the positioning post 34 and an upper face 302 of the dissipation head 32 and therefore is compressed as shown in FIG. 10 and FIG. 11. The springs 35 restore to push the heat-dissipation assembly 30 to move downwards. When the long axis 631 of the first cams 61 are located in the upright direction, the springs 35 is pushed to move upwards to be compressed, so that the heat-dissipation assembly 30 separates from the supporting frame 20 with the dissipation head 32 separates from the chip module. At this moment, the springs 35 save energy and intend to shift downward. Combined with FIG. 8, the operating member 50 is rotated to drive the short axis 632 of the first cams 61 in the upright direction, the upward push of the long axis 631 is removed, resulting that the springs 35 reset and shift downwards to bring the dissipation head 32 to shift downwards and contacts the chip module. When the electrical socket 100 has no chip module inserted, rotate the operating member 50 as shown in FIG. 8, the short axis of the first cams are in the upright direction, the dissipation head 32 protrudes into the chip-receiving area 11.

Furthermore, the electrical socket 10 includes a pair of the second cams 62, which are identical to the first cams 61. The second cams 62 are received in corresponding receiving slots 21 and pivoted to the supporting frame 20 by third shafts 43. The first cam 61 and corresponding second cam 62 are located side by side and have teeth 64 mesh with each other. The first cams 61 are located proximate to the locking portion 31, the second cams 62 are located proximate to the first shaft 41. The two pairs of the cams at opposite receiving slots are symmetrical to each other, thereby forming a symmetrical rotating mechanism to keep the dissipation head 32 contact the top of the chip module and to increase the force on the operating member. The operating member 50 with the two pairs of the cams and the shifts commonly construct an elevating mechanism to drive a lift movement and a descent movement of the heat-dissipation assembly 30.

The operating member 50 includes two side portions 51 and a transverse bar 52 connected with the side portions 51, each of the side portions 51 includes four bars connected in turn to get a turning portion 521 of a quadrangle shape and a circle hole 53 at an outside of the turning portion 521. The circle holes 521 are retained with the second shafts 42. The transverse bar 51 and the circle holes 53 are located at opposite corners. In this embodiment, the turning portion 521 is of a square shape. The operating member 50 has an anti-turning hole 54 communicating with the circle hole 521. The first cam 61 has an anti-turning boss 614 at an inside thereof. Therefore, the operating member 50 brings the first cams to rotate via the anti-turning boss in the circle hole. In other embodiment, the circle hole and the anti-turning hole are united as a non-circle retaining hole. The second shaft 42 is constructed with a non-circle shape to get an un-rotating retaining engagement with the retaining hole.

The first cam 61 includes a circle portion 611 and a shear portion 612 which is formed by cutting a side of the circle portion 611. The circle portion 611 and the shear portion provide contacting faces. The circle portion 611 has a hole 613 at a center of the circle portion 611, the second shafts are fitted in the hole 613, the teeth are disposed on the circle portion 611. The long axis 631 is defined along a diameter of the circle portion 611, the short axis 632 is defined in a diameter perpendicular to the shear portion 612. The transverse bar 52 is retained with the two side portions via the fourth shafts 44.

Referring to FIG. 2, the heat-dissipation assembly 30 has grooves 33 receiving the turning portions 521, the transverse bar 52 exposes to an upper face of the heat-dissipation assembly 30. Referring to FIG. 3, in the seating state, the transverse bar 52 is located proximate to the locking portion 31. When the user pulls the transverse bar 53, the turning portion 521 rolls to another end of the heat-dissipation assembly as shown in FIG. 8, wherein the turning portion 521 bring the shear portion 621 to face upward and the heat-dissipation assembly 30 move downwards to contact the chip module.

The above-mentioned embodiments are only preferred embodiments of the present invention, and should not limit the scope of the present invention, any simple equivalent changes and modifications made according to the claims of the present invention and the contents of the description should still belong to the present invention.

1. An electrical socket for testing a chip module, comprising:
a socket base having a chip-receiving area;
a supporting frame having a first shaft pivotably connected with one end of the socket base;
a heat-dissipation assembly having a dissipation head and being retained on the supporting frame and movable along the supporting frame;
an operating member having two side portions;
a pair of first cams, each of the first cams and a corresponding side portion being retained with a second shaft, the second shaft being pivotably connected with the supporting frame; and
a pair of second cams, each of the second cams being retained with a third shaft, the third shaft being pivotably connected with the supporting frame; wherein
the first cams and corresponding second cams are located side by side, each of the first and second cams has a long axis and a short axis;
the heat-dissipation assembly is rotatable to seat on the socket base so the long axes of the first and second cams are oriented in an upright direction to keep the heat-dissipation assembly away from the supporting frame with a gap; and
the operating member is rotatable to orient the short axes of the first and second cams in the upright direction so the heat-dissipation assembly moves downwards and contact the chip module.

2. The electrical socket as claimed in claim 1, wherein the supporting member has a middle opening aligned with the chip-receiving area and two receiving slots at opposite sides of the middle opening, and the first cams and corresponding second cams are received in corresponding receiving slots.

3. The electrical socket as claimed in claim 1, wherein the first cam and a corresponding second cam have teeth meshing each other.

4. The electrical socket as claimed in claim 3, wherein each of the first and second cams has a circle portion and a shear portion, the teeth are disposed on the circle portion, the circle portion has a retaining hole at a center thereof, and the second shaft is received and retained in the retaining hole.

5. The electrical socket as claimed in claim 4, wherein the short axis is defined along a diameter of the circle portion perpendicular to the shear portion, and the long axis is defined along a diameter perpendicular to the short axis.

6. The electrical socket as claimed in claim 1, wherein the heat-dissipation assembly comprises a locking portion at another end thereof opposite to the first shaft, and the locking portion is latched with the socket base after the heat-dissipation assembly is rotated to the socket base.

7. The electrical socket as claimed in claim 1, wherein the operating member comprises a transverse bar connected with the two side portions, each of the side portions comprises a turning portion and a retaining hole, and the second shaft is received and retained in the retaining hole.

8. The electrical socket as claimed in claim 1, wherein the first cams are located proximate to the locking portion, and the second cam are located proximate to the first shaft.

9. The electrical socket as claimed in claim 1, wherein the operating member comprises a transverse bar connected with the two side portions, each of the side portions comprises a turning portion, and a circle hole and an anti-turning hole communicating with the circle hole, the second shaft is received and retained in corresponding circle hole and an ant-turning boss defined at the first cam is received and retained in the anti-turning hole.

10. The electrical socket as claimed in claim 1, wherein the heat-dissipation assembly comprises positioning posts and springs, a lower end of the positioning post goes across the dissipation head and is retained with the supporting frame, and the springs are set around corresponding positioning post and press downwards against the dissipation head.

11. An electrical socket for testing a chip module, comprising:
a socket base having a chip-receiving area;
a supporting frame having a first end pivoted to the socket base by a first shaft and a locking portion at a second end opposite to the first end to latch with the socket base;
a heat-dissipation assembly having a dissipation head and retained on the supporting frame;
an operating member having two side portions;
a pair of first cams; and
a pair of second cams; wherein
the first cam and a corresponding second cam are located side by side, the first cam and a corresponding side portion are retained with a second shaft, the second shaft is pivoted to the supporting frame; and
the second cam is retained with a third shaft, and the third shaft is pivoted to the supporting frame.

12. The electrical socket as claimed in claim 11, wherein each of the first cams and the second cams has teeth, and the teeth of the first cam and corresponding second cam mesh with each other.

13. The electrical socket as claimed in claim 12, wherein each of the first cams and the second cams has a circle contacting face and a shear contacting face trimming one part of the circle contacting face, the teeth are defined on the circle contacting face, and the shear contacting face has no tooth.

14. The electrical socket as claimed in claim 11, wherein the heat-dissipation assembly separates from the supporting frame to keep the dissipation head distanced from the chip module when the shear contacting face is facing upwards.

15. The electrical socket as claimed in claim 14, wherein the heat-dissipation assembly moves downwards to keep the dissipation head in contact with the chip module when the shear contacting face is oriented at a position perpendicular to the supporting frame.

16. An electrical socket for testing a chip module, comprising:
a socket base having a chip-receiving area;
a supporting frame being pivotably connected with the socket base by a first shaft at one end thereof and having a locking portion at another end thereof to latch with the socket base after the supporting frame is rotated to seat on the socket base;
a heat-dissipation assembly retained on the supporting frame and having springs; and
an operating member retained with a pair of first cams, the first cams being pivotably connected with the supporting frame by a pair of second shafts, each of the first cams having a long axis and a short axis;
wherein the operating member is rotatable to orient the long axes of the first cams in an upright direction to push the heat-dissipation assembly away from the supporting frame by a gap and to orient the short axes of the first cams in the upright direction to reset the heat-dissipation assembly to move downwards by the springs.

17. The electrical socket as claimed in claim 16, further comprising four positioning posts extending across the heat-dissipation assembly and retained with the supporting frame, and wherein each of the springs is disposed around a corresponding positioning post and limited between an upper end of the positioning post and a face of the heat-dissipation assembly.

18. The electrical socket as claimed in claim 16, further comprising a pair of second cams and a pair of third shafts, and wherein the second cams are pivotably connected with the supporting frame by the pair of third shafts, each of the first cams and the second cams has teeth, the teeth of the first cam and teeth of a corresponding second cam mesh each other.

19. The electrical socket as claimed in claim 16, wherein each of the first and second cams has a circle contacting face and a shear contacting face, the short axis is defined along a diameter perpendicular to the shear contacting face, and the long axis is defined along a diameter through the circle contacting face.
